(19) United States
(12) Patent Application Publication
(10) Pub. No.: US 2022/0141989 A1
(43) Pub. Date: May 5, 2022

(54) ELECTRONIC DEVICE CHARGER

(71) Applicant: HOSIDEN CORPORATION, Osaka (JP)

(72) Inventors: Shuya YOKOBORI, Gunma (JP); Yutaka SANDA, Gunma (JP); Koji MINAMI, Gunma (JP); Tatsuya MORISHITA, Gunma (JP)

(73) Assignee: HOSIDEN CORPORATION, Osaka (JP)

(21) Appl. No.: 17/502,577

(22) Filed: Oct. 15, 2021

(30) Foreign Application Priority Data
Oct. 29, 2020 (JP) 2020-181190

(51) Int. Cl. H05K 7/20; H02J 7/00; H05K 7/14

(52) U.S. Cl. CPC H05K 7/209; H05K 7/1427; H02J 7/0042

(57) ABSTRACT

An electronic device charger includes: a lower case that is a housing with an upper surface thereof opened, the lower case including a pair of projecting portions and raised portions, the pair of projecting portions being provided at positions facing each other on inner side surfaces, the raised portions being formed by extending, in an upper direction, parts of the inner side surfaces at positions of the projecting portions; a board housed in the lower case, the board being clamped by the pair of projecting portions; and a heat sink that functions as an upper case covering the board and in which an arrangement pitch of heat dissipation fins disposed on an upper surface of the heat sink is an integral fraction of a predefined width of a heat generating component in an arrangement direction of the heat dissipation fins.

### TECHNICAL FIELD

The present invention relates to an electronic device charger having a heat sink structure.

### BACKGROUND ART

Japanese Registered Utility Model No. 3189642 (referred to below as Patent Literature 1) discloses a conventional example of an electronic device charger that receives electric power from a cigar lighter socket or a USB receptacle and supplies the electric power to an electronic device.

The electronic device charger in Patent Literature 1 includes a USB A plug disposed at the tip thereof, a side input-output terminal disposed on the side wall, and a terminal for electronic devices that supplies electric power to an electronic device.

The electronic device charger in Patent Literature 1 has the function of receiving electric power by directly connecting the USB A plug to a USB A receptacle of a personal computer, and supplying the electric power to an electronic device via the terminal for electronic devices. In addition, the electronic device charger has the function of receiving electric power through the shield of the USB A plug and the side input-output terminal by inserting the electronic device charger into a cigar lighter socket.

Since conventional electronic device chargers generate heat disadvantageously, many components such as a heat conductive sheet, a heat sink, and a metal housing are required as the heat dissipation structure. Since the number of components increases, the heat transfer efficiency between components may be degraded, whereby the heat dissipation efficiency may be degraded. In addition, size reduction is difficult because the number of components increases. When a cooling fan is used for heat dissipation, the product becomes large and the product cost increases disadvantageously.

### SUMMARY OF THE INVENTION

Accordingly, an object of the present invention is to provide a compact electronic device charger that has excellent heat dissipation efficiency.

An electronic device charger according to the present invention includes a lower case, a board, and a heat sink. The lower case is a housing with an upper surface thereof opened, and includes a pair of projecting portions and raised portions, the pair of projecting portions being provided at positions facing each other on inner side surfaces, the raised portions being formed by extending, in an upper direction, parts of the inner side surfaces at positions of the projecting portions. The board is housed in the lower case, and is clamped by the pair of projecting portions. The heat sink functions as an upper case covering the board, and an arrangement pitch of heat dissipation fins disposed on an upper surface of the heat sink is an integral fraction of a predefined width of a heat generating component in an arrangement direction of the heat dissipation fins.

### Effects of the Invention

The electronic device charger according to the present invention is compact and has excellent heat dissipation efficiency.

### BRIEF DESCRIPTION OF THE DRAWINGS

FIG. 1 is a perspective view of an electronic device charger according to a first embodiment.

FIG. 2 is an exploded perspective view of the electronic device charger according to the first embodiment.

FIG. 3 is a plan view of the electronic device charger according to the first embodiment.

FIG. 4 is a sectional view of the electronic device charger according to the first embodiment taken along the cutting line in FIG. 3.

### DETAILED DESCRIPTION

An embodiment of the present invention will be described in detail below. Components having the same function are given the same reference numeral to omit duplicate descriptions.

### First Embodiment

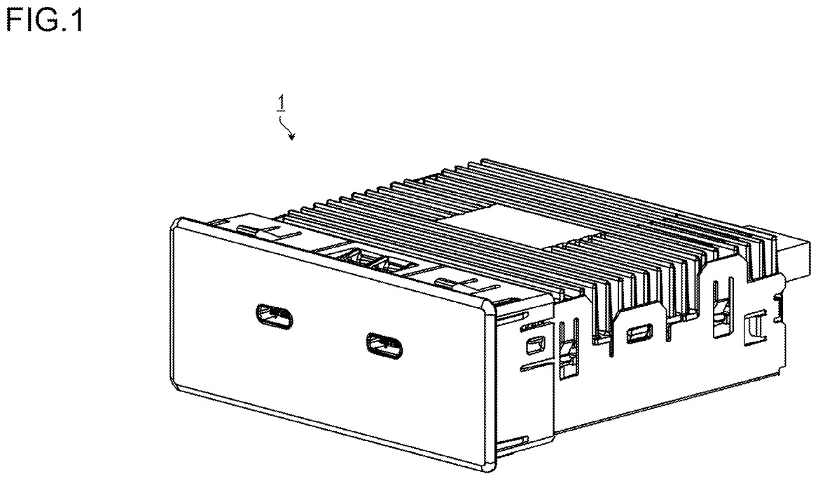

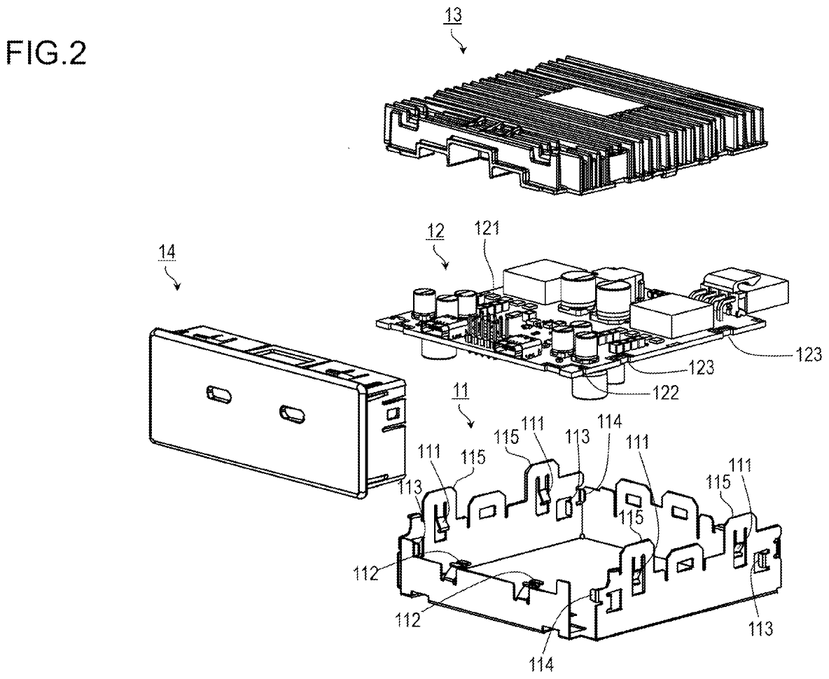

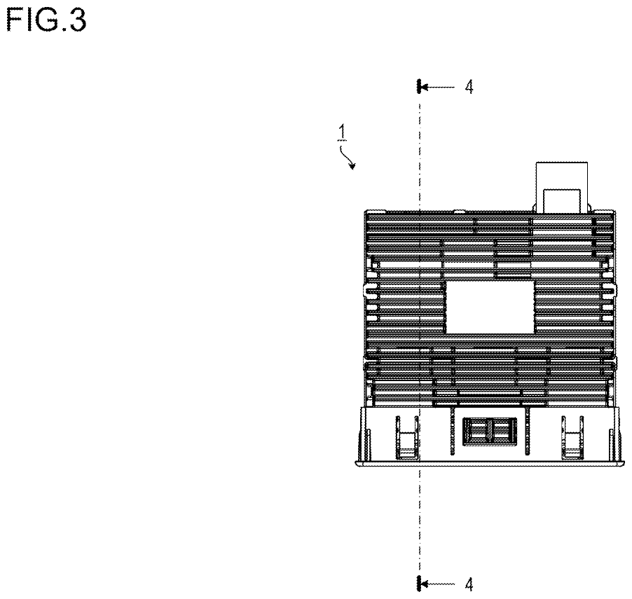

The structure of an electronic device charger according to a first embodiment will be described below with reference to FIGS. 1 to 4. An electronic device charger 1 according to the embodiment has a substantially rectangular parallelepiped shape having two sockets on the front surface and a plug on the back surface as illustrated in FIG. 1 and includes a lower case 11, a board 12, a heat sink 13, and a front cover 14 as illustrated in FIG. 2. Hereinafter, the details of the structures of the required components will be described with reference to FIG. 2.

<Lower Case 11>

The lower case 11 is a metal housing with the upper surface thereof opened and has two pairs of projecting portions 111 raised inward at positions facing each other on the left and right inner side surfaces. In addition, two overhanging portions 112 raised inward are provided on the front inner side surface and a total of four projections 113 raised inward are provided on the left and right inner side surfaces. The board 12, which will be described later, is placed on the overhanging portions 112 and the projections 113. In addition, positioning claws 114 raised inward are provided at a total of two diagonal positions on the left and right inner side surfaces. In addition, parts of the inner side surfaces at the positions of the projecting portions 111 are extended in the upper direction to form raised portions 115.

<Board 12>

The board 12 is housed in the lower case 11. A heat generating component 121 is mounted at the position illustrated in FIG. 2 on the board 12. Grooves 122 are provided at positions on the left and right side surfaces of the board 12 that are engaged with the positioning claws 114. The positioning claws 114 are engaged with the grooves 122, whereby the board 12 is positioned with respect to the lower case 11. Grooves 123 are provided on the left and right side surfaces of the board 12, and the board 12 is clamped when the grooves 123 come into contact with the projecting portions 111. The projecting portions 111 and the grooves 123 are soldered to each other. This transfers heat from the board 12 to the lower case 11, thereby improving the heat dissipation efficiency. In addition, heat dissipation is made more efficient by the raised portion 115 formed by extending, in the upper direction, the parts of the inner side surfaces at the positions of the projecting portions 111 of the lower case 11. Further heat dissipation effects can be obtained by forming the board 12 as a copper inlay heat dissipation board.

<Heat Sink 13>

Heat dissipation fins 131 are provided at predetermined intervals on the upper surface of the heat sink 13. The heat sink 13 functions as the upper case that covers the board 12. The heat sink 13 may be made of, for example, metal. Alternatively, the heat sink 13 may be made of a heat conductive resin. When the heat sink 13 is made of a heat conductive resin, the weight can be lighter than in metal.

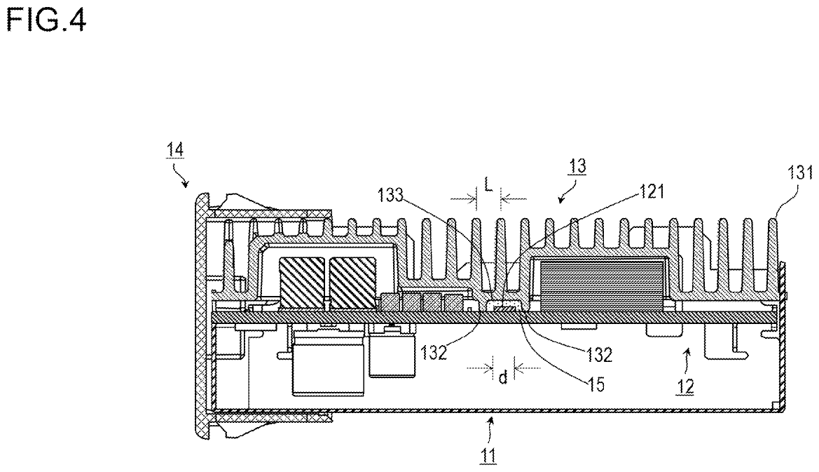

As illustrated in FIG. 4, the arrangement pitch L of the heat dissipation fins 131 is an integral fraction of the width d of the heat generating component 121 in the arrangement direction of the heat dissipation fins 131. It is preferable that the arrangement pitch of the heat dissipation fins 131 is defined as described above and the heat dissipation fins 131 are disposed directly above both ends of the heat generating component 121. The lower surface of the heat sink 13 has a recess 133 that encloses the upper portion and the side portion of the heat generating component 121. The recess 133 has legs 132, which are in contact with the board 12. The space formed between the recess 133 and the heat generating component 121 is filled with a heat dissipation gel 15. The heat dissipation gel 15 can be held well and the outflow can be suppressed by providing the legs 132 and the recess 133. Since the space is filled with the heat dissipation gel 15, the heat generated from the heat generating component 121 is easily transferred to the heat sink 13 via the heat dissipation gel 15 and the heat dissipation effect is enhanced.

<Front Cover 14>

The front cover 14 is fitted so as to cover the front surface of the assembly formed by combining the lower case 11, the board 12, and the heat sink 13 as illustrated in FIG. 2, whereby the individual components are fixed.

The foregoing description of the embodiment of the invention has been presented for the purpose of illustration and description. It is not intended to be exhaustive and to limit the invention to the precise form disclosed. Modifications or variations are possible in light of the above teaching. The embodiment was chosen and described to provide the best illustration of the principles of the invention and its practical application, and to enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

What is claimed is:

1. An electronic device charger comprising:
a lower case that is a housing with an upper surface thereof opened, the lower case including a pair of projecting portions and raised portions, the pair of projecting portions being provided at positions facing each other on inner side surfaces, the raised portions being formed by extending, in an upper direction, parts of the inner side surfaces at positions of the projecting portions;
a board housed in the lower case, the board being clamped by the pair of projecting portions; and
a heat sink that functions as an upper case covering the board and in which an arrangement pitch of heat dissipation fins disposed on an upper surface of the heat sink is an integral fraction of a predefined width of a heat generating component in an arrangement direction of the heat dissipation fins.

2. The electronic device charger according to claim 1, wherein
a lower surface of the heat sink has a recess that encloses an upper portion and a side portion of the heat generating component.

3. The electronic device charger according to claim 2, wherein
a space formed between the recess and the heat generating component is filled with a heat dissipation gel.

4. The electronic device charger according to claim 1, wherein
the projecting portions and the board are soldered to each other.

5. The electronic device charger according to claim 2, wherein
the projecting portions and the board are soldered to each other.

6. The electronic device charger according to claim 3, wherein
the projecting portions and the board are soldered to each other.
